(19) United States
(12) Patent Application Publication
(10) Pub. No.: US 2008/0024141 A1
(43) Pub. Date: Jan. 31, 2008

(54) METHOD AND APPARATUS FOR INSULATING RIGGERS

(76) Inventor: Hugh Michael Oppen Pratt, Bristol (GB)

Correspondence Address: FITCH EVEN TABIN AND FLANNERY, 120 SOUTH LA SALLE STREET, SUITE 1600, CHICAGO, IL, 60603-3406, US

(21) Appl. No.: 11/836,703

(22) Filed: Aug. 9, 2007

Related U.S. Application Data
(62) Division of application No. 11/071,763, filed on Mar. 2, 2005.

(30) Foreign Application Priority Data
Mar. 3, 2004 (GB) 0404856.7

(51) Int. Cl. G01R 27/00; H01B 17/02

(52) U.S. Cl. 324/552; 174/138 R

(57) ABSTRACT

A method and apparatus for insulating riggers includes coupling a first end of an insulator body to a load and coupling a second end of the insulator body to a tag line. The insulator body includes an outer surface comprising at least one rib. The at least one rib extends from the insulator body in a plane substantially perpendicular to an axis between the first and second ends.

### CROSS REFERENCE TO RELATED APPLICATIONS

This is a divisional application of U.S. application Ser. No. 11/071,763, filed Mar. 2, 2005, which claims foreign priority under 35 U.S.C. § 119 to United Kingdom Application No. GB 0404856.7, filed Mar. 3, 2004, both of which such applications are hereby incorporated herein by reference.

### BACKGROUND

Where heavy loads are lifted by cranes or other similar mobile lifting apparatus, a particular danger exists from overhead power lines. If a part of a crane contacts a power line, a worker who is in electrical contact with the load, such as a rigger who may be controlling the lateral movement of the load, for example by means of ropes or tag lines, may be in danger of severe electrocution as current passes to earth. This is because the rope or tag line will become conductive if for example the rope becomes wet. A contact with a power line may be known as an electrical strike. Amongst fatalities in crane-related accidents, such electrocutions amount to a significant proportion of total fatalities. Accidents of this nature are known to give rise to many serious injuries each year.

Another problem arises where cranes or similar lifting apparatus are operated near radio frequency (RF) transmission sources, for example, radar or radio transmission towers. The crane may act as an antenna such that the RF energy induces a potential in the crane. Such a potential may cause injury to a worker who is in electrical contact with the crane. This may be fatal or a non-fatal shock, which may produce an RF burn. Although usually non-fatal, such RF shocks are still considered to be disadvantageous.

It has been previously proposed to incorporate a device to insulate a load from a lifting apparatus in the form of a device which is interposed into a loaded line. Reference is made to UK patent number GB2274899B, granted to the applicant. This document describes an insulator unit which is interposed in a load transmission path between a lifting apparatus and a suspended load.

However, a load insulator interposed between the crane and the load would not give protection to a rigger where a power line is contacted by a load, the load suspended from an insulator, in the case where a tag line is made conductive because it is wet or contaminated by conductive substances such as mud, the rigger is in electrical contact with the power line. This contact is likely to result in the rigger being electrocuted. Thus, such a load insulator does not provide protection from electrocution to a rigger where a power line is contacted by any component hanging below the load insulator of the lifting apparatus.

Embodiments of the present invention aim to address the above problem.

### SUMMARY OF DESCRIBED EMBODIMENTS

According to one aspect of the present invention, there is provided an insulating link for interposition into a tag line, said tag line being attached to a load and for cooperation with a rigger, said insulating link comprising: a first end for attachment to a load; a second end for attachment to a tag line; an insulator body arranged between the first and second ends to reduce or prevent conduction of electricity through the insulating link.

According to a second aspect of the present invention, there is provided the use of an insulating link in a tag line, wherein said tag line is attached to a load and said insulating link is electrically insulating.

Additional embodiments are described and claimed. It should further be understood that numerous changes to the disclosed embodiments can be made without departing from the spirit or scope of the present descriptions. The preceding summary therefore is not meant to limit the scope of this description.

### BRIEF DESCRIPTION OF THE DRAWINGS

Embodiments of the invention are described, by way of example only, with reference to the following drawings in which:

FIG. 1 illustrates an embodiment of the present invention in use;

FIG. 2 is a view of a first embodiment of the invention; and

FIG. 3 shows schematically an electronic testing and monitoring system.

### DETAILED DESCRIPTION OF THE ILLUSTRATED EMBODIMENTS

Embodiments of the present invention may provide an insulating link which minimizes or eliminates the flow of current over the outside of the insulating link, thereby forcing most or all of the current to flow through the inside thereof. In addition, the exterior of the insulating link is completely covered with a water-proof seal to reduce or prevent entry of water or moisture into the interior of the insulating link.

In embodiments of the present invention, the insulating link may have an elongated body extending between and coupled to opposite end lugs. The body may have an electrically insulating and water-proof finish in the form of plastic or similar material. The result is an exterior having increased electrical resistance, which directs most if not all current produced by exposure to high voltages to flow through the inside of the insulating link.

According to embodiments of the present invention, the insulating link may be of integral, one-piece construction that may comprise a polymer or other appropriate material. One preferred plastics material is polyurethane.

According to an alternative embodiment of the present invention, the elongated body of the insulating link is configured so as to have a plurality of surrounding ribs or sheds, which function to increase a creepage distance on an outside surface thereof. Selected ones of the ribs are larger and extend further from the body than the intervening ribs, and function to shield the smaller intervening ribs from rain and also to inhibit or prevent the formation of a water coating over the entire outer surface of the body. In addition, the larger ribs function to inhibit or prevent the formation of a coating of dirt over the entire outer surface of the body if the insulating link is placed on the ground. Reduction in water and dirt coatings on the outside of the insulating link can greatly reduce the conductivity of the outside surface of the insulating link, which can direct current to flow through the inside of the insulating link instead.

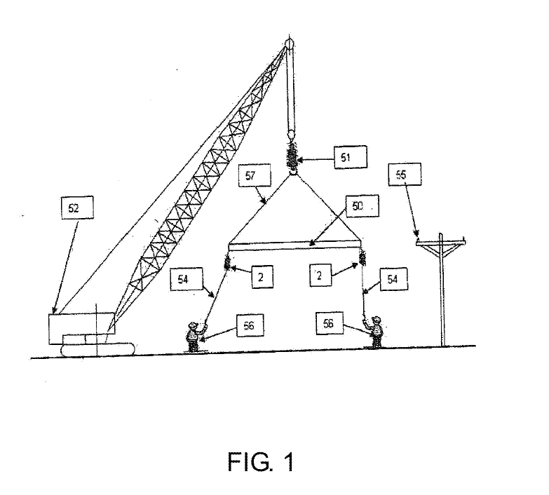

FIG. 1 illustrates an embodiment of the present invention in use. A load 50 is suspended from a lifting apparatus 52 by wires 57 via a load insulator 51. In FIG. 1 lifting apparatus 52 is a mobile crane. In the case where no insulating link is fitted the induced potential is generated in the whole crane, load and wires and the power line contact can occur with any part of the lifting apparatus, wires and load. If an insulating link is fitted the induced potential is generated in the load and wires and the power line contact can occur with any part of the wires and load. Insulating links 2 are interposed between the load 50 and tag lines 54, electrically insulating the tag lines 54 from the load 50. In particular, the riggers 56 are also electrically isolated from the lifting apparatus 52 and the load 50, such that if an electrical strike were to occur wherein a part of the load 50 or any part of the lifting apparatus 52 comes into contact with a power line 55, the rigger 56 is protected from electrocution.

The insulating links 2 additionally protect the riggers 56 from potential induced in the lifting apparatus 52 or load 50 by the presence of radio frequency electromagnetic radiation.

A creepage distance is the shortest path between two electrically insulated conductive parts measured along the surface of an insulator placed therebetween. An adequate creepage distance protects against tracking, a process that produces a partially conducting path of localized deterioration on the surface of an insulator material as a result of the electric discharges on or close to an insulator surface. The voltage required to bring about insulator failure due to tracking is reduced by:
the presence of humidity in the atmosphere in contact with the insulator device;
the presence of contaminants on the surface of the insulator;
the exposure of the insulator surface to corrosive chemicals; and
the altitude at which the equipment is operated.

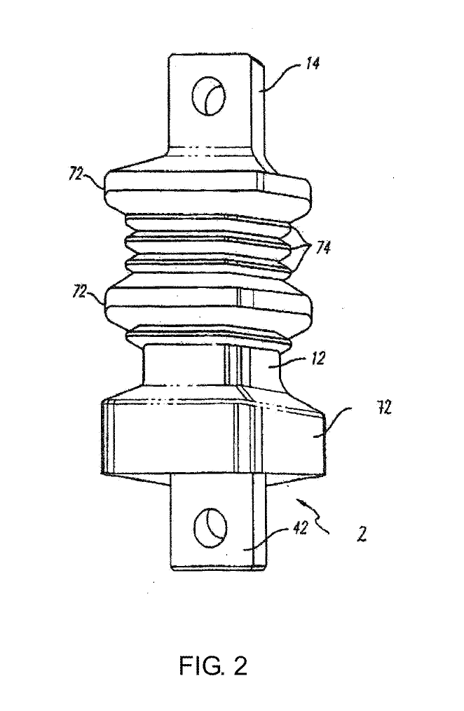

FIG. 2 shows an embodiment of an insulating link according to the present invention. A body portion 12 of the insulating link 2 is provided with a plurality of ribs or sheds 72 and 74 which extend around the circumference thereof and increase the creepage distance. The smaller ribs 74 are of like size and tend to prevent formation of a continuous layer of water, such as from rain, or a continuous layer of dirt or other contamination, either of which forms a conductive path which encourages current flow over the outside of rather than through the inside of the insulating link. Nevertheless, if sufficient water forms, or if the insulating link is exposed to a substantial amount of dirt or contamination, such as by being laid on the ground, then there may still be a tendency for current to flow over the outside of the insulating link.

In accordance with an embodiment of the invention, the insulating link 2 is provided with at least one rib 72 which is substantially larger in diameter than the body 12 so as to extend outwardly therefrom. The at least one rib 72 protects an at least one smaller rib 74 from contamination by rain water. The at least one rib 72 also protects an at least one smaller rib 74 from contamination by mud and other contaminants if the insulating link 2 is placed on dirty ground.

The at least one rib of the insulating link 2 may be substantially square, substantially rounded or substantially polygonal in cross section. The at least one rib may alternatively have a cross section of any shape.

Typically the force to be supported by the tag line will be equivalent to the weight of the order of a few hundred pounds. Connecting lugs 14 & 42 are for attachment to a tag line suspended by a lifting apparatus and to a tag line, respectively. Thus, the insulating link is interposed in a tag line path between the suspended load and a rigger who is holding the tag line.

The insulating link is in one embodiment, a solid polymer or similar material. It is appreciated that other materials may be selected. For example, the material may be electrically insulating at voltages which might occur should an electrical power line be contacted (typically, 110 volts to 56,000 volts). The material may also have reasonable strength properties. One example of a suitable material is a composite of a polymer material such as synthetic polyurethane. It is appreciated that most known insulative materials may not be 100% electrically insulative. However, materials may be selected to reduce conduction of electricity through the insulating link to a level deemed to increase safety for most applications, particularly for a voltage range which may be encountered such as 110 volts to 56,000 volts, for example.

The insulating link would normally be used attached to a load with a tag line freely suspended therefrom. Alternatively, the insulating link may be attached between two lengths of tag line, a first length of tag line is attached between the load and the insulating link, the second length of tag line having one end attached to the insulating link and having the other end free for cooperation with a rigger. A rigger may cooperate with the tag line by holding it. A rigger may further cooperate with a tag line by holding it and applying a force to it by pulling on it.

The afore mentioned insulating link is intended to be a basic design to perform the role of providing an electrically insulating connection between a rigger coupled by a tag line to a suspended load.

In the further alternative embodiments of the present invention that follow, additional features are added to this basic device for increased functionality.

In another aspect or embodiment of the present invention, the outer casing of the insulating link is difficult to hold by hand. This is realized by the presence of ribs on the surface of the insulating link. Sloping surfaces also make the insulating link difficult to hold by hand. This reduces the likelihood of the rigger holding the insulating link instead of the rope attached to it. It is disadvantageous for the rigger to hold the insulating link because this can reduce the effectiveness of the insulating link by reducing the length of insulation between the rigger and the tag line.

In alternative embodiments of the present invention, the insulating link 2 is provided with associated electronics which may serve one or more of three primary functions: first, to provide monitoring of the insulating properties; secondly, to allow for recording of incidences of electrical strikes; and thirdly, to provide a lifetime expiry indication to limit the period of use of the insulating link 2 for safety reasons.

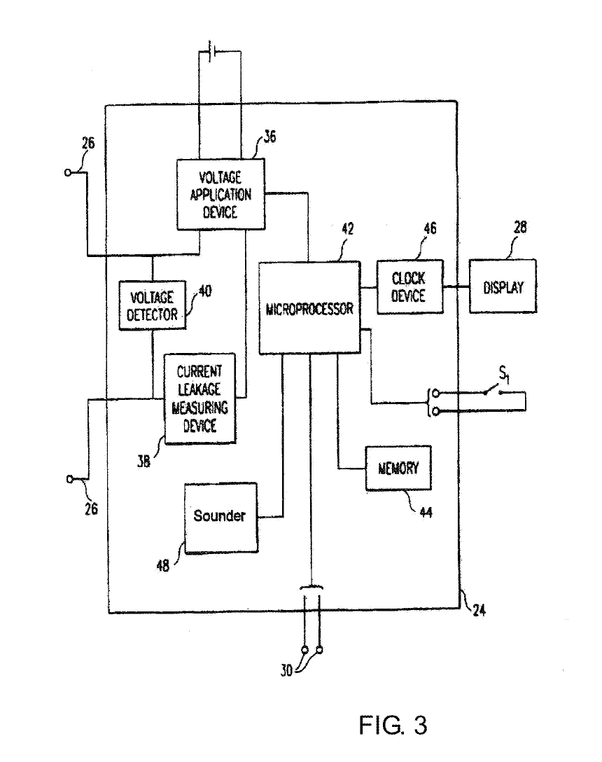

FIG. 3 shows a schematic of a circuit means for providing these functions. An electronic module 24 is connected to opposite ends of the insulating link via connections 26. The opposite ends of the insulating link may comprise the regions of the insulating link around each connecting lug 14 and 42. The module 24 includes means for applying a voltage 36 across the insulating link, and means for measuring the current leakage 38, which will be indicative of the resistance and hence insulating condition of the insulating link. The apparatus may be arranged such that the insulating condition is continuously monitored. Alternatively, the insulating condition is only monitored prior to use: a test mode may be initiated prior to use by manually closing switch S1. When the insulating link condition is monitored, the insulating link resistance is measured; if this is above a predetermined value, an “OK” signal is output to a display 28, indicating to a user that the insulating link 2 is safe for use. The display 28 may be an LED or LCD display or sounder 48. The sounder 48 may be adapted to sound if the insulating condition of the insulating link is faulty.

The electronic module 24 also includes voltage measuring means 40 and a microprocessor 42 having memory means 44 arranged to record the electrical history of the device, and in particular whether a device has been subjected to an electrical strike, detected by the voltage measuring means, and if so recording the day and time of the event. Data ports 30 allow for external communication with the microprocessor to retrieve the device history. Clock means 46 are provided to indicate via the display 28 when the device has been used for a predetermined period of time, or for a predetermined number of times. It may be arranged that the display or sounder 48 merely indicates to a user that the device must be returned to the manufacturers for recalibration and testing purposes, for example annually, or alternatively it might be arranged that the device is made inoperative. This provides an important safety function.

The applicant hereby discloses in isolation each individual feature described herein and any combination of two or more such features, to the extent that such features or combinations are capable of being carried out based on the present specification as a whole in the light of the common general knowledge of a person skilled in the art, irrespective of whether such features or combinations of features solve any problems disclosed herein, and without limitation to the scope of the claims. The applicant indicates that aspects of the present invention may consist of any such individual feature or combination of features. In view of the foregoing description it will be evident to a person skilled in the art that various modifications may be made within the scope of the invention.

What is claimed is:

1. A method of insulating a rigger from a load, comprising:
coupling a first end of an insulator body to a load; and
coupling a second end of the insulator body to a tag line;
wherein the insulator body includes an outer surface comprising at least one rib.

2. The method of claim 1, wherein said outer surface is waterproof.

3. The method of claim 1, wherein said at least one rib extends from the insulator body in a plane substantially perpendicular to an axis between the first and second ends.

4. The method of claim 3, wherein said insulator body has at least two ribs, at least one of the ribs being a large rib that extends further from the axis between the first and second ends than an at least one small rib.

5. The method of claim 4, wherein said at least one large rib protects said at least one small rib from contamination.

6. The method of claim 1, wherein said at least one rib is adapted to increase a creepage distance between the first and second ends on the outer surface of the insulator body.

7. The method of claim 1, wherein said at least one rib is adapted to reduce the electrical conductivity of the insulator body.

8. The method of claim 1, wherein said at least one rib is substantially square in cross section.

9. The method of claim 1, wherein said at least one rib is substantially rounded in cross section.

10. The method of claim 1, wherein said at least one rib is substantially polygonal in cross section.

11. The method of claim 1, wherein said insulator body is constructed of a polymer material and is of an integral, one-piece construction.

12. The method of claim 1, wherein said insulator body is constructed of a composite of polymer materials and is of an integral, one-piece construction.

13. The method of claim 1, wherein said insulator body is constructed of a synthetic polyurethane and is of an integral, one-piece construction.

14. The method of claim 1, wherein said first end, said second end and said insulator body are parts of a single item.

15. The method of claim 1 wherein the insulator body further comprises a microprocessor and a warning means adapted to output a warning signal if a detected resistance drops below a predetermined value.

16. The method of claim 15, wherein the warning means comprises a display, and a switch means for actuation by a user to actuate a test of the resistance of the insulator body, such that a warning signal is displayed on the display means if the resistance is below the predetermined value.
